(19) United States
(12) Patent Application Publication
(10) Pub. No.: US 2023/0207563 A1
(43) Pub. Date: Jun. 29, 2023

(54) GATE ALL AROUND COMPLEMENTARY METAL-OXIDE-SEMICONDUCTOR FIELD EFFECT TRANSISTORS

(71) Applicant: International Business Machines Corporation, Armonk, NY (US)

(72) Inventors: Kangguo Cheng, Schenectady, NY (US); Julien Frougier, Albany, NY (US); Ruilong Xie, Niskayuna, NY (US)

(21) Appl. No.: 17/565,367

(22) Filed: Dec. 29, 2021

(51) Int. Cl. H01L 27/092; H01L 29/06; H01L 29/423; H01L 29/49; H01L 29/786; H01L 21/02; H01L 21/28; H01L 21/8238; H01L 29/66

(52) U.S. Cl. CPC H01L 27/092; H01L 29/0665; H01L 29/42392; H01L 29/4908; H01L 29/78696; H01L 21/0259; H01L 21/02532; H01L 21/28088; H01L 21/823807; H01L 21/823842; H01L 29/66545; H01L 29/66553; H01L 29/66742

(57) ABSTRACT

A complementary metal-oxide-semiconductor field effect transistor structure (C-MOSFET) includes a substrate; a dielectric pillar that is embedded in and recessed into the substrate; a gate pillar that contacts the dielectric pillar and protrudes from the substrate; a first stack of semiconductor nanosheets that protrude from a first side of the gate pillar; and a second stack of semiconductor nanosheets that protrude from a second side of the gate pillar, opposite the first side.

### BACKGROUND

The present invention relates to the electrical, electronic, and computer arts, and more specifically, to field effect transistors (FETs).

A forksheet FET is a top of complementary metal-oxide-semiconductor (CMOS) FET in which p-type FET (pFET) fins are separated from nFET fins by a dielectric pillar. Because the dielectric pillar, rather than gate metal, is adjacent to inner ends of the fins, the ends are not gated.

### SUMMARY

Principles of the invention provide techniques for gate all around complementary metal-oxide-semiconductor field effect transistors.

In one aspect, an exemplary complementary metal-oxide-semiconductor field effect transistor structure (C-MOSFET) includes a substrate; a dielectric pillar that is embedded in and recessed into the substrate; a gate pillar that contacts the dielectric pillar and protrudes from the substrate; a first stack of semiconductor nanosheets that protrude from a first side of the gate pillar; and a second stack of semiconductor nanosheets that protrude from a second side of the gate pillar, opposite the first side.

According to another aspect, an exemplary integrated circuit structure includes a plurality of metal lines; and a plurality of complementary metal-oxide-semiconductor field effect transistors (C-MOSFETs), essentially as discussed above, that are interconnected by the plurality of metal lines.

According to another aspect, an exemplary method for fabricating a gate-all-around complementary metal-oxide-semiconductor field effect transistor (C-MOSFET) includes forming, on a substrate, a first stack of nanosheets and a second stack of nanosheets separated by a dielectric pillar; forming a first gate stack around the first stack of nanosheets; forming a second gate stack around the second stack of nanosheets; forming a trench by recessing the dielectric pillar partially below the bottom of each stack of nanosheets; and filling the trench with a gate pillar.

In view of the foregoing, techniques of the present invention can provide substantial beneficial technical effects. For example, one or more embodiments provide one or more of:

Increasing effective device width relative to spacing between adjacent FETs, thereby enabling the same performance (in terms of ON resistance) with reduced nanosheet width to reduce device size.

Improving device electrostatics and thus reducing leakage current compared to previous forksheet FETs.

Increasing drive current (with a comparable chip footprint) compared to previous forksheet FETs.

Reducing stand-by power consumption (due to leakage current) when transistors are supposed to be in an off-state compared to previous fork nanosheet FETs.

Some embodiments may not have these potential advantages and these potential advantages are not necessarily required of all embodiments. These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 depicts a forksheet field effect transistor (FET).

FIG. 2 depicts a gate-all-around forksheet FET, according to an exemplary embodiment.

FIG. 3 depicts a flow chart of steps in a process for fabricating the gate-all-around forksheet FET shown in FIG. 2.

FIG. 4 depicts a top view of a preliminary structure in the process of FIG. 3, according to an exemplary embodiment.

FIG. 5 depicts a sectioned view of the preliminary structure shown in FIG. 4.

FIG. 6 depicts a top view of an intermediate structure in the process of FIG. 3, according to an exemplary embodiment.

FIG. 7 depicts a sectioned view of the intermediate structure shown in FIG. 6.

FIG. 8 depicts a top view of an intermediate structure in the process of FIG. 3, according to an exemplary embodiment.

FIG. 9 depicts a sectioned view of the intermediate structure shown in FIG. 8.

FIG. 10 depicts a sectioned view of the intermediate structure shown in FIG. 8.

FIG. 11 depicts a top view of an intermediate structure in the process of FIG. 3, according to an exemplary embodiment.

FIG. 12 depicts a sectioned view of the intermediate structure shown in FIG. 11.

FIG. 13 depicts a sectioned view of the intermediate structure shown in FIG. 11.

FIG. 14 depicts a top view of an intermediate structure in the process of FIG. 3, according to an exemplary embodiment.

FIG. 15 depicts a sectioned view of the intermediate structure shown in FIG. 14.

FIG. 16 depicts a schematic view of a portion of an integrated circuit that includes a plurality of the gate-all-around forksheet FETs shown in FIG. 2.

### DETAILED DESCRIPTION

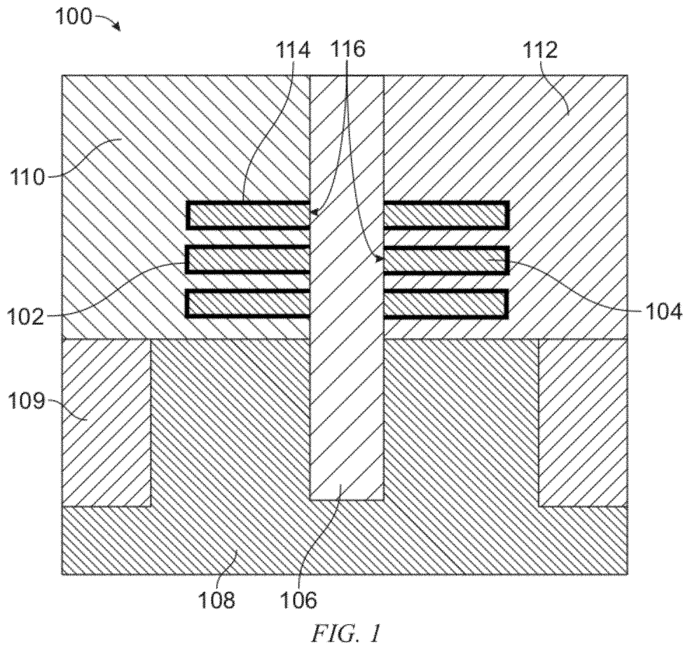

FIG. 1 depicts a forksheet field effect transistor (FET) 100. A forksheet FET is a top of complementary metal-oxide-semiconductor (CMOS) FET in which p-type FET (pFET) fins 102 are separated from nFET fins 104 by a dielectric pillar 106. The fins and dielectric pillar are formed on a substrate 108, e.g., a silicon substrate. Shallow trench isolation 109 bounds the forksheet FET 100 and separates it from adjacent FETs. A p-type gate metal 110 surrounds the pFET fins 102 (except for their ends 116 that are adjacent to the dielectric pillar 106) and an n-type gate metal 112 surrounds the nFET fins 104 (except for their ends 116 that are adjacent to the dielectric pillar 106). Dielectric 114 coats the fins 102, 104 to separate them from the gate metals. Because the gate metals are not adjacent to the ends 116 of the fins 102, 104, the ends 116 are not gated. As a result, an effective channel width of each fin is approximately equal to the length of the two sides and the end that are adjacent to the gate metal, not including the length of the end that is adjacent to the dielectric pillar.

An aspect of some embodiments of the invention is to provide a gate-all-around forksheet FET by replacing the dielectric pillar 106, at the nanosheet stack level, with a high-k/metal “gate pillar,” after high-k/metal gate (HK/MG) patterning and formation of the p-FET gate and n-FET gate, thereby (1) increasing the effective device width, and (2) improving electrostatics. Dielectric recess, HK/MG deposition, and chemical-mechanical polishing (CMP), all of which are helpful in replacing the dielectric pillar 106 with the gate pillar, are mature processes in semiconductor manufacturing. The skilled person, given the teachings herein, will be able to implement the invention.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures.

A number of different precursors may be used for the epitaxial deposition of the in situ doped semiconductor material. In some embodiments, the gas source for the deposition of an epitaxially formed in situ doped semiconductor material may include silicon (Si) deposited from silane, disilane, trisilane, tetrasilane, hexachlorodisilane, tetrachlorosilane, dichlorosilane, trichlorosilane, disilane and combinations thereof. In other examples, when the in situ doped semiconductor material includes germanium, a germanium gas source may be selected from the group consisting of germane, digermane, halogermane, dichlorogermane, trichlorogermane, tetrachlorogermane and combinations thereof. Examples of other epitaxial growth processes that can be employed in growing semiconductor layers described herein include rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE).

By “in-situ” it is meant that the dopant that dictates the conductivity type of doped layer is introduced during the process step, for example epitaxial deposition, that forms the doped layer. The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

As used herein, the term “conductivity type” denotes a dopant region being p-type or n-type. As further used herein, “p-type” refers to the addition of impurities to an intrinsic semiconductor that creates deficiencies of valence electrons. In a silicon-containing substrate, examples of p-type dopants, i.e., impurities include but are not limited to: boron, aluminum, gallium and indium. As used herein, “n-type” refers to the addition of impurities that contribute free electrons to an intrinsic semiconductor. Examples of n-type dopants, i.e., impurities in a silicon-containing substrate include but are not limited to antimony, arsenic and phosphorous.

As an exemplary subtractive process, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1st Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

In one or more embodiments, work function material (WFM) layers are disposed over the gate dielectric layer in both the nFET and pFET regions (in embodiments having both types of regions) to complete the gate stacks. Non-limiting examples of suitable work function (gate) metals include p-type work function materials and n-type work function materials. P-type work function materials include compositions such as ruthenium, palladium, platinum, cobalt, nickel, and conductive metal nitride like TiN, WN, or any combination thereof. N-type work function materials include compositions such as hafnium, zirconium, titanium, tantalum, aluminum, metal carbides (e.g., hafnium carbide, zirconium carbide, titanium carbide, and aluminum carbide), aluminides, or any combination thereof.

In one or more embodiments, appropriately doped polysilicon can be used as a gate material.

Work function material(s) may be deposited by a suitable deposition process, for example, ALD, CVD, PECVD, PVD, plating, and thermal or e-beam evaporation. Pinch-off of work function material between semiconductor fins is essentially avoided during deposition. The WFM layer is removed from one of the nFET and pFET regions in structures including both types of regions while the other region is protected. An SC1 etch, an SC2 etch or other suitable etch processes can be employed to remove the selected portion of the originally deposited WFM layer. A new WFM layer suitable for the region is then deposited. A device formed in the nFET region will accordingly include a WFM layer (gate electrode) having a first composition while a device in the pFET region will have a WFM layer having a second composition. The pFET WFM generally will have a greater work function than the nFET WFM. For example, the WFM employed in an nFET region may be a Ti, Al, TiAl, TiAlC or TiAlC layer or a metal stack such as TiN/TiAl/TiN, TiN/TiAlC/TiN, TiN/TaAlC/TiN, or any combination of an aluminum alloy and TiN layers. The WFM layer employed in the pFET region may, for example, be a TiN, TiC, TaN or a tungsten (W) layer. The threshold voltage (Vt) of FET devices is sensitive to the thickness of work function materials such as titanium nitride (TiN).

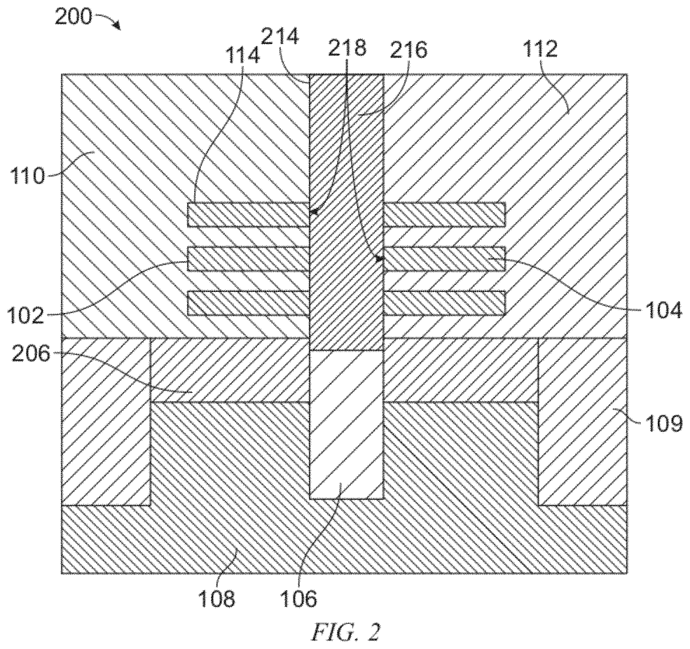

FIG. 2 depicts a gate-all-around forksheet FET 200, according to an exemplary embodiment. Components of the FET 200 that are similar to those of the FET 100 are numbered alike. Note that in the FET 200, the dielectric pillar 106 does not extend all the way to the top of the structure; instead, the dielectric pillar is slightly recessed into a bottom dielectric isolation 206, atop the substrate 108. A gate pillar 216 extends upward from the recessed dielectric pillar 106 between inward ends 218 of the fins 102, 104. A dielectric 214 separates the gate pillar 216 from the fins 102, 104. Because the gate metal 216 is adjacent to the ends 218 of the fins 102, 104, an effective channel width of each fin is approximately equal to the lengths of the two sides and the two ends.

For a design fin size of 5 nanometers (nm) thick and 25 nm wide, replacing an upper part of the dielectric pillar 106 with the gate pillar 216 increases an effective device width by 8% (5 nm/(5 nm+25 nm+25 nm+5 nm)). The greater effective channel width directly translates to drive current gain (i.e. more drive current achieved for the same device footprint). Furthermore, replacing the dielectric pillar with high-k/metal gate material enables all sides of each nanosheet to be wrapped with a gate stack so that each nanosheet device has a true gate all around (GAA) structure. With all sides of each nanosheet gated by a gate stack, there is stronger control of a nanosheet channel by a gate. As a result, a GAA structure improves the electrostatics of its nanosheet channels when compared with the conventional fork nanosheet structure in which one side of nanosheet abutting the dielectric pillar is not gated. Improving transistor electrostatics directly leads to a reduction in leakage current. Also, for a given leakage current target, improved electrostatics allows a reduction of threshold voltage and thus improves transistor drive current.

The basic structure of FIG. 2 admits of several variations. In one variation, the gate pillar has a work function similar to the pFET gate. This variation directly improves pFET drive current and electrostatics, directly improves nFET electrostatics, and indirectly improves nFET performance. For example, the nFET performance improves because for the same leakage current, a lower threshold voltage can be adopted in the inventive device when compared with a conventional fork nanosheet device. A lower threshold voltage means a higher overdrive (the difference between operation voltage and threshold voltage). Everything else being the same, the more overdrive a transistor is subjected to, a higher drive current the transistor can deliver. Also, for a given drive current target and leakage current target, one can take advantage of the improved electrostatics/performance to reduce the transistor size, allowing more transistors on a given chip area.

In another variation, the gate pillar has a work function similar to the nFET gate. This variation directly improves nFET drive current and electrostatics, directly improves pFET electrostatics, and indirectly improves pFET performance. In another variation, the gate pillar has a mid-gap-like work function, i.e. a work function that is intermediate between a work function of the pFET gate and a work function of the nFET gate. This variation directly improves both nFET and pFET electrostatics, and indirectly improves pFET and nFET performance as discussed above. The skilled artisan will appreciate that improvements in electrostatics can advantageously be translated to performance improvements.

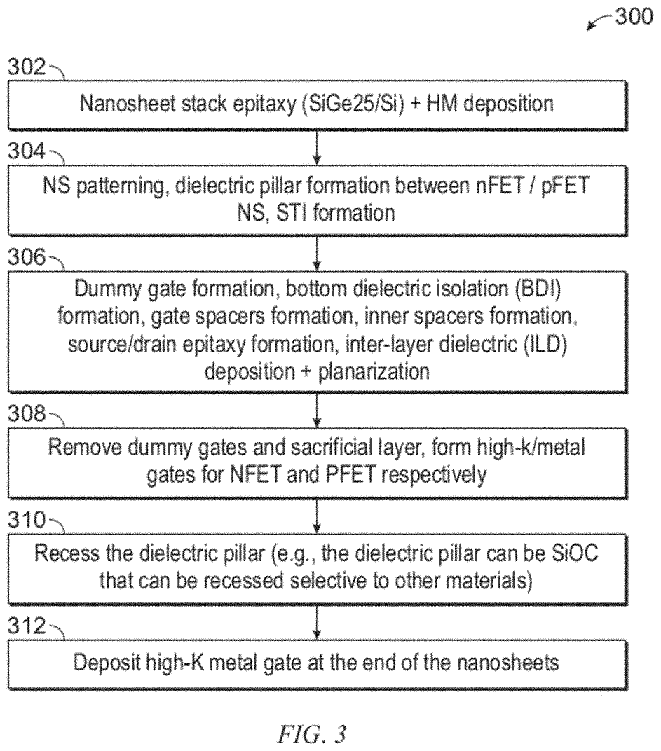

FIG. 3 depicts a flow chart of steps in a process 300 for fabricating the gate-all-around forksheet FET 200, shown in FIG. 2.

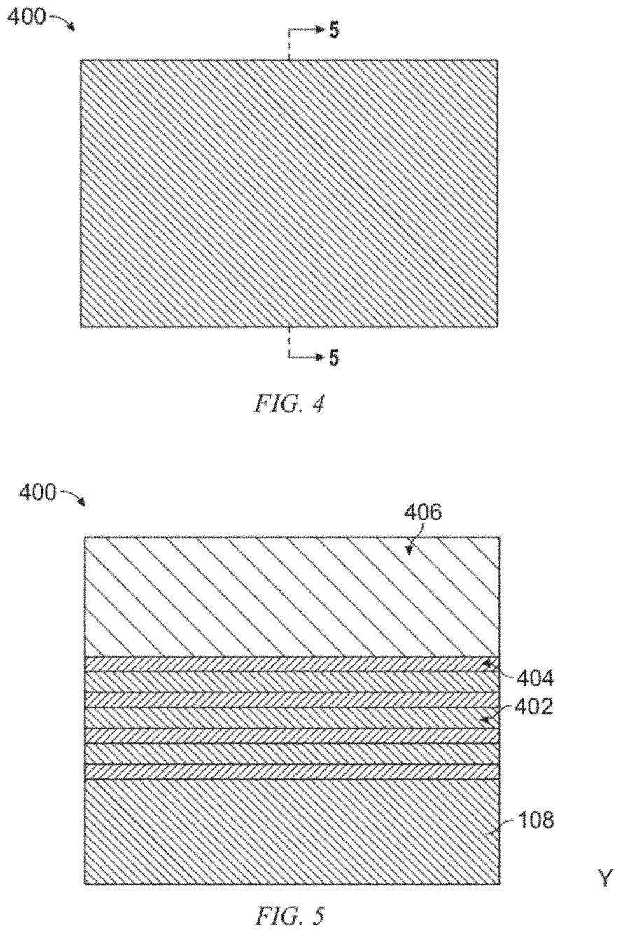

At 302, form a preliminary structure 400 (refer also to FIG. 4 and FIG. 5) by nanosheet stack epitaxy (alternating layers of silicon 402 and silicon-25% germanium (SiGe25) 404) and depositing a hard mask 406. Although SiGe25 is provided as an example, suitable compositions for a sacrificial layer includes any ratio of silicon and germanium for which the sacrificial layer is selective to the semiconductor (channel) structure for a given etch process.

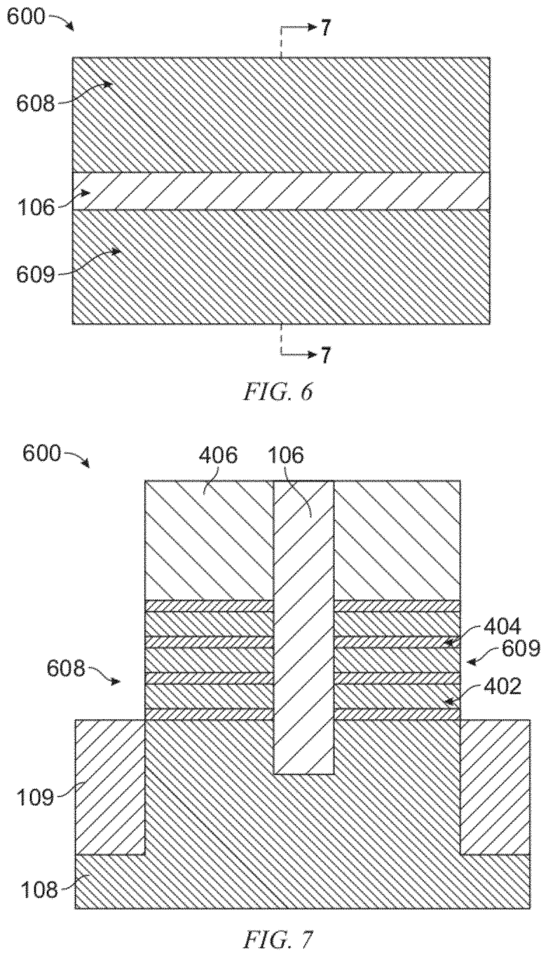

At 304, form an intermediate structure 600 (refer also to FIG. 6 and FIG. 7) by patterning pFET nanosheets 608 and nFET nanosheets 609, forming a dielectric pillar 106 between pFET nanosheets 608 and nFET nanosheets 609, and forming shallow trench isolation 109 in the substrate 108.

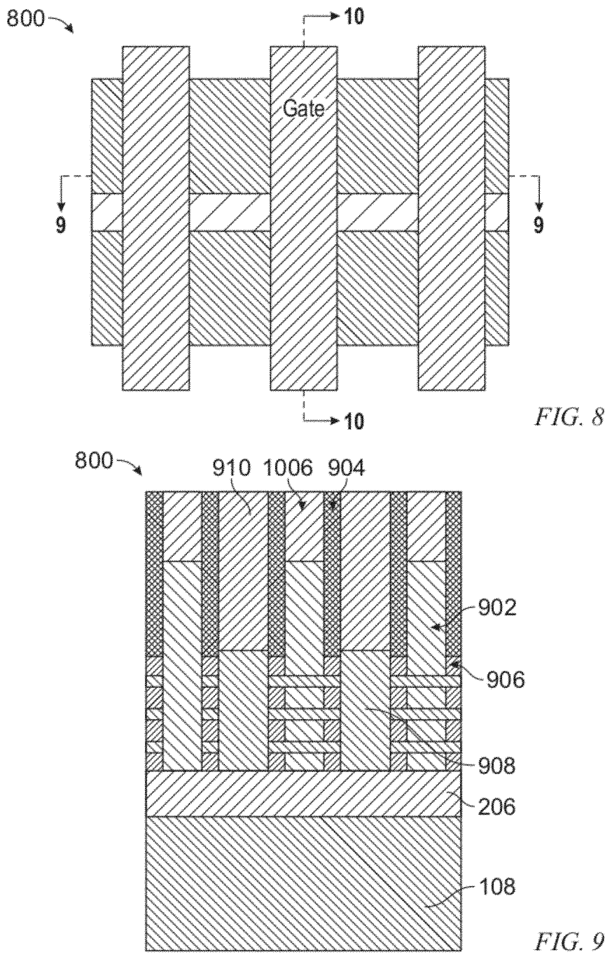

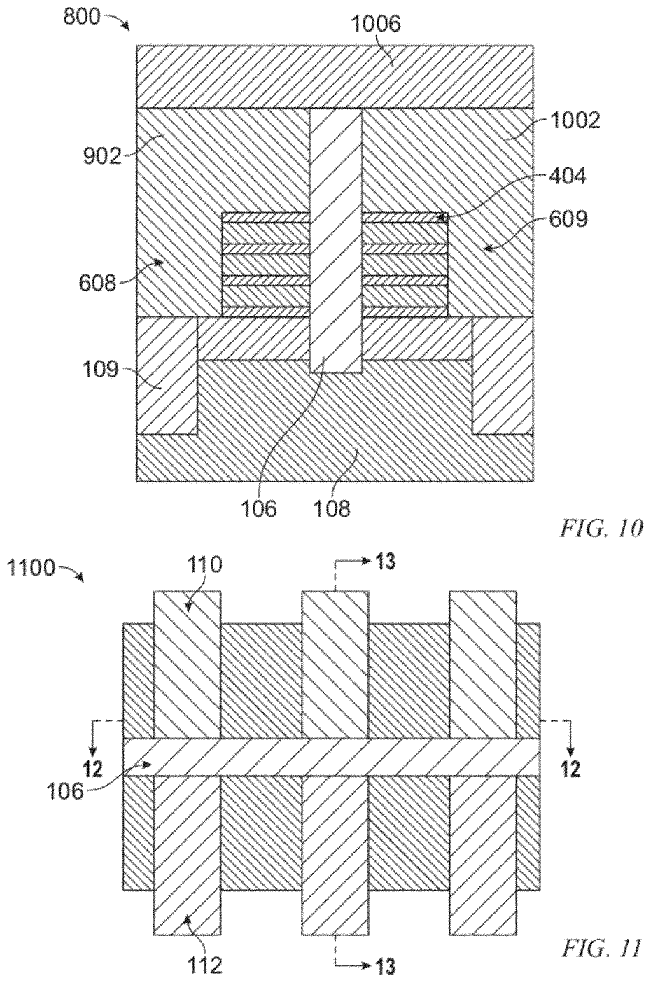

At 306, form an intermediate structure 800 (refer also to FIG. 8, FIG. 9, and FIG. 10) by forming dummy gates 902 and 1002, optionally bottom dielectric isolation (BDI) 206, gate spacers 904, and inner spacers 906; epitaxially growing source/drain structures 908; depositing inter-layer dielectric (ILD) 910; capping the dummy gates 902 and 1002 with a hard mask 1006; and planarizing (e.g., chemical mechanical polishing).

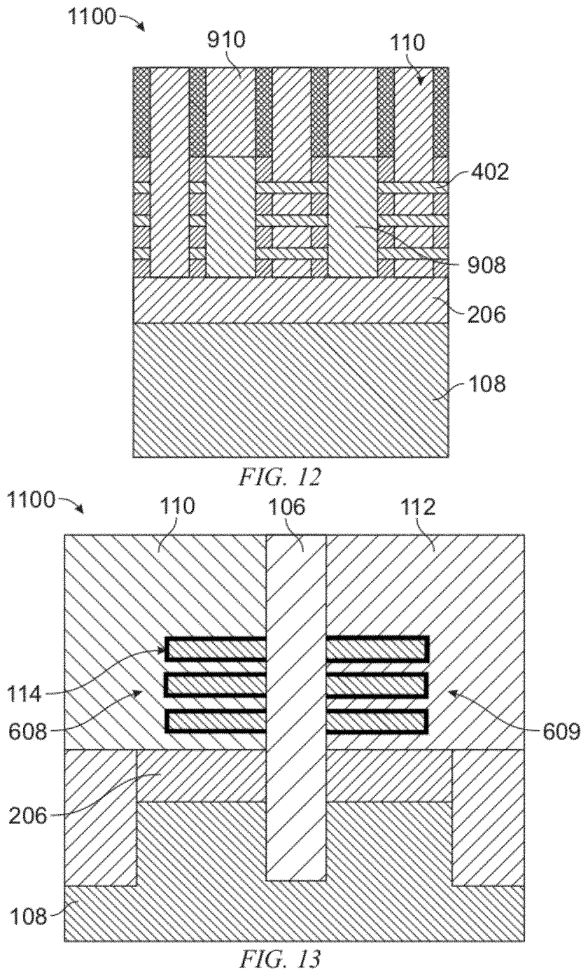

At 308, form an intermediate structure 1100 (refer also to FIG. 11, FIG. 12, and FIG. 13) by removing the dummy gates 902, 1002 (last shown in FIG. 10) and removing the sacrificial layer of SiGe25 404 (last shown in FIG. 10), followed by high-k/metal gate formation of p-gate 110 and n-gate 112. The intermediate structure 1100 still includes a full-height dielectric pillar 106, which advantageously separates the p-gate 110 from the n-gate 112 during gate formation.

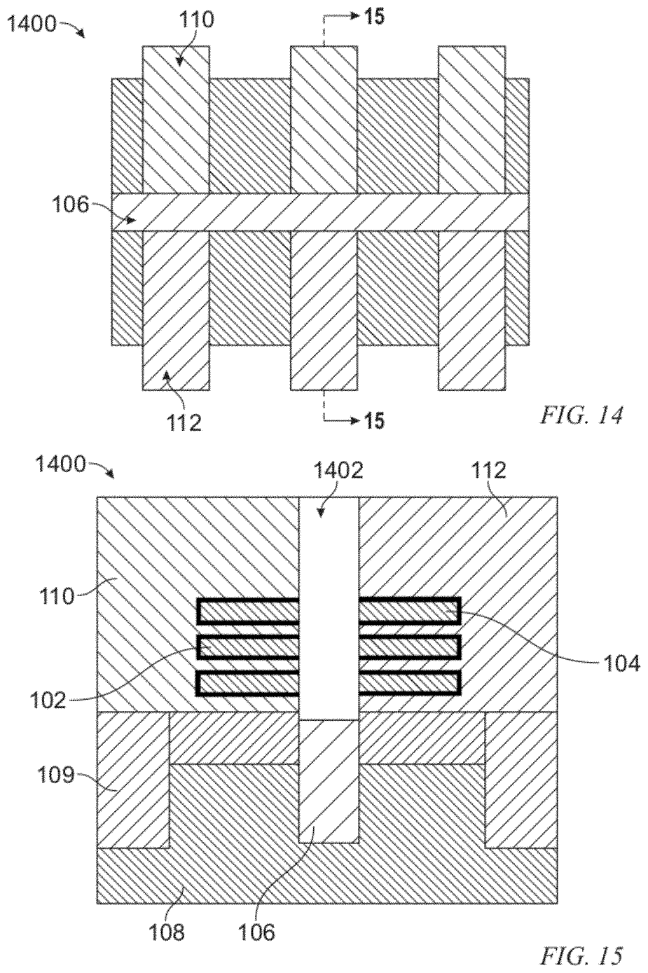

At 310, form an intermediate structure 1400 (refer also to FIG. 14 and FIG. 15) by recessing the dielectric pillar 106 to form a trench 1402. For example, the dielectric pillar can be SiOC or another organic glass that can be recessed selective to other materials

At 312, form the gate-all-around FET 200 (shown in FIG. 2) by depositing the high-k/metal material of the gate pillar 216 into the trench 1402 (last seen in FIG. 15).

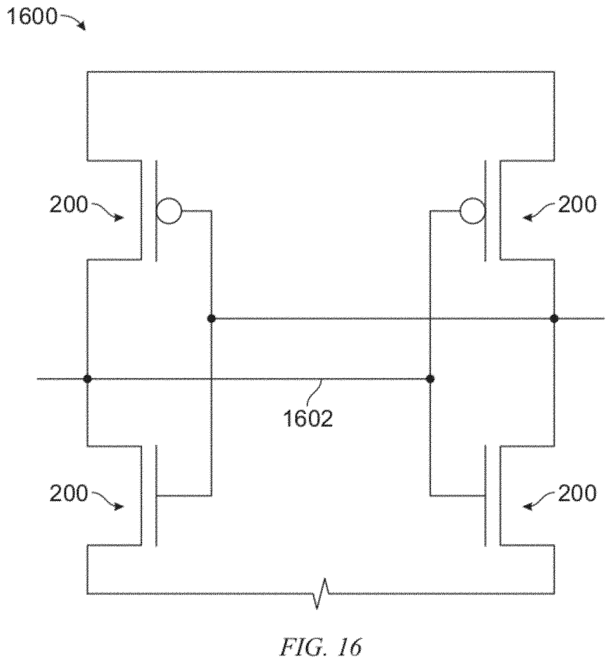

FIG. 16 depicts a schematic view of a portion of an integrated circuit 1600 that includes a plurality of the gate-all-around forksheet FETs 200 that are shown in FIG. 2. Metal lines 1602 interconnect the FETs 200.

Given the discussion thus far, it will be appreciated that, in general terms, an exemplary complementary metal-oxide-semiconductor field effect transistor structure (C-MOSFET) 200 includes a substrate 108; a dielectric pillar 106 that is embedded in and recessed into the substrate; a gate pillar 216 that contacts the dielectric pillar and protrudes from the substrate; a first stack of semiconductor nanosheets 102 that protrude from a first side of the gate pillar; and a second stack of semiconductor nanosheets 104 that protrude from a second side of the gate pillar, opposite the first side. In one or more embodiments, a first gate stack 110 surrounds the first stack of semiconductor nanosheets; and a second gate stack 112 surrounds the second stack of semiconductor nanosheets.

In one or more embodiments, the gate pillar is of a same work function as the first gate stack. In one or more embodiments, the gate pillar is of a same work function as the second gate stack. In one or more embodiments, a work function of the gate pillar is intermediate between a work function of the first gate stack and a work function of the second gate stack. In one or more embodiments, the first gate stack comprises an n-type work function metal gate. For silicon or silicon germanium nanosheet channels, an n-type work function metal gate has a work function between 4.1 eV to 4.65 eV. In one or more embodiments, the second gate stack comprises a p-type work function metal gate. For silicon or silicon germanium nanosheet channels, a p-type work function metal gate has a work function between 4.65 eV to 5.2 eV. In one or more embodiments, at least one of the first gate stack, the gate pillar, and the second gate stack consists essentially of a metal, or a metallic compound

According to another aspect, an exemplary integrated circuit structure 1600 includes a plurality of metal lines 1602; and a plurality of complementary metal-oxide-semiconductor field effect transistors (C-MOSFETs) 200, essentially as discussed above, that are interconnected by the plurality of metal lines

According to another aspect, an exemplary method 300 for fabricating a gate-all-around complementary metal-oxide-semiconductor field effect transistor (C-MOSFET) includes, at 302, forming, on a substrate 108, a first stack of nanosheets 102 and a second stack of nanosheets 104 that are separated by a dielectric pillar 106. At 308, form a first gate stack 110 around the first stack of nanosheets and form a second gate stack 112 around the second stack of nanosheets. At 310, form a trench 1402 by recessing the dielectric pillar partially below the bottom of each stack of nanosheets. At 312, fill the trench with a gate pillar 216.

In one or more embodiments, the gate pillar is of a same work function as the first gate stack. In one or more embodiments, the gate pillar is of a same work function as the second gate stack. In one or more embodiments, a work function of the gate pillar is intermediate between a work function of the first gate stack and a work function of the second gate stack. In one or more embodiments, the first gate stack comprises an n-type work function metal gate. For silicon or silicon germanium nanosheet channels, an n-type work function metal gate has a work function between 4.1 eV to 4.65 eV. In one or more embodiments, the second gate stack comprises a p-type work function metal gate. For silicon or silicon germanium nanosheet channels, a p-type work function metal gate has a work function between 4.65 eV to 5.2 eV.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A complementary metal-oxide-semiconductor field effect transistor structure, comprising:
a substrate;
a dielectric pillar that is embedded in and recessed into the substrate;
a gate pillar that contacts the dielectric pillar and protrudes from the substrate;
a first stack of semiconductor nanosheets that protrude from a first side of the gate pillar; and
a second stack of semiconductor nanosheets that protrude from a second side of the gate pillar, opposite the first side.

2. The structure of claim 1, further comprising:
a first gate stack that surrounds the first stack of semiconductor nanosheets; and
a second gate stack that surrounds the second stack of semiconductor nanosheets.

3. The structure of claim 2, wherein the gate pillar is of a same work function as the first gate stack.

4. The structure of claim 2, wherein the gate pillar is of a same work function as the second gate stack.

5. The structure of claim 2, wherein a work function of the gate pillar is intermediate between a work function of the first gate stack and a work function of the second gate stack.

6. The structure of claim 2, wherein the first gate stack comprises a metal gate that has a work function of between 4.1 eV to 4.65 eV.

7. The structure of claim 2, wherein the second gate stack comprises a metal gate that has a work function of between 4.65 eV to 5.2 eV.

8. An integrated circuit structure, comprising:
a plurality of metal lines; and
a plurality of complementary metal-oxide-semiconductor field effect transistors (C-MOSFETs), interconnected by the plurality of metal lines, wherein each of the C-MOSFETs comprises:
a gate pillar that contacts the dielectric pillar and protrudes from the substrate;
a substrate;
a dielectric pillar that is embedded in and recessed into the substrate;
a first stack of semiconductor nanosheets that protrude from a first side of the gate pillar; and
a second stack of semiconductor nanosheets that protrude from a second side of the gate pillar, opposite the first side.

9. The structure of claim 8, further comprising:
a first gate stack that surrounds the first stack of semiconductor nanosheets; and
a second gate stack that surrounds the second stack of semiconductor nanosheets.

10. The structure of claim 9, wherein the gate pillar is of a same work function as the first gate stack of the same FET.

11. The structure of claim 9, wherein the gate pillar is of a same work function as the second gate stack of the same FET.

12. The structure of claim 9, wherein a work function of the gate pillar is intermediate between a work function of the first gate stack of the same FET and a work function of the second gate stack of the same FET.

13. The structure of claim 9, wherein the first gate stack comprises an n-type work function metal gate.

14. The structure of claim 9, wherein the second gate stack comprises a p-type work function metal gate.

15. The structure of claim 9, wherein at least one of the first gate stack, the gate pillar, and the second gate stack consists essentially of a metal, or a metallic compound

16. A method for fabricating a gate-all-around complementary metal-oxide-semiconductor field effect transistor, comprising:
forming, on a substrate, a first stack of nanosheets and a second stack of nanosheets separated by a dielectric pillar;
forming a trench by recessing the dielectric pillar partially below the bottom of each stack of nanosheets; and
filling the trench with a gate pillar.

17. The method of claim 16, further comprising:
forming a first gate stack around the first stack of nanosheets, wherein the first gate stack comprises an n-type work function metal; and
forming a second gate stack around the second stack of nanosheets, wherein the second gate stack comprises a p-type work function metal.

18. The method of claim 17, wherein the gate pillar is of a same work function as the first gate stack.

19. The method of claim 17, wherein the gate pillar is of a same work function as the second gate stack.

20. The method of claim 17, wherein a work function of the gate pillar is intermediate between a work function of the first gate stack and a work function of the second gate stack.
